(19) United States
(12) Patent Application Publication
(10) Pub. No.: US 2021/0257570 A1
(43) Pub. Date: Aug. 19, 2021

(54) PHOTOELECTRIC CONVERSION ELEMENT AND METHOD OF PRODUCING PHOTOELECTRIC CONVERSION ELEMENT

(71) Applicant: SHARP KABUSHIKI KAISHA, Osaka (JP)

(72) Inventors: HIROSHI SUGIMURA, Osaka (JP); SHINTARO MIYANISHI, Osaka (JP)

(21) Appl. No.: 17/162,597

(22) Filed: Jan. 29, 2021

(30) Foreign Application Priority Data
Feb. 19, 2020 (JP) 2020-026351

(51) Int. Cl. H01L 51/42; H01L 51/00

(52) U.S. Cl. CPC H01L 51/4226; H01L 2251/303; H01L 51/0048; H01L 51/0034

(57) ABSTRACT

The photoelectric conversion element includes an electron transport layer, a hole transport layer, and a light absorption layer arranged between the electron transport layer and the hole transport layer. The light absorption layer contains a perovskite compound having an acicular crystal structure. The hole transport layer contains a carbon nanotube and a polyvinyl butyral resin. A degree of butyralization of the polyvinyl butyral resin is preferably equal to or more than 60 mol % and equal to or less than 80 mol %.

### BACKGROUND OF THE INVENTION

### Field of the Invention

The present invention relates to a photoelectric conversion element and a method of producing the photoelectric conversion element.

### Description of the Background Art

A photoelectric conversion element is used, for example, in an optical sensor, a copying machine, and a solar cell. Among these, the solar cell is gradually and genuinely widespread as a typical method of using renewable energy. As the solar cell, a solar cell using an inorganic photoelectric conversion element (for example, a silicon-based solar cell, a CIGS-based solar cell, and a CdTe-based solar cell) is widely used.

On the other hand, as the solar cell, a solar cell using an organic photoelectric conversion element (for example, an organic thin film solar cell and a dye-sensitized solar cell) is also being studied. The solar cell using such an organic photoelectric conversion element can be produced by a coating process, and thus, a production cost may possibly be reduced. Therefore, the solar cell using the organic photoelectric conversion element is expected as a next-generation solar cell.

In recent years, as the organic photoelectric conversion element, a photoelectric conversion element employing a compound (hereinafter, sometimes referred to as “perovskite compound”) having a perovskite type crystal structure for a light absorption layer is being studied. For example, in a photoelectric conversion element described in Japanese Unexamined Patent Application Publication No. 2014-72327 (hereinafter, referred to as Patent Document 1), a thin layer formed of a photosensitive material having the perovskite type crystal structure and a thin layer formed of a conductive material made of a carbon nanotube are laminated.

However, a crystal structure of the perovskite compound is easily affected by a moisture (humidity) present in a production environment. Specifically, when the photoelectric conversion element using the perovskite compound is formed under air atmosphere (particularly under air atmosphere with a humidity of equal to or more than 50% RH), the perovskite compound is formed in an acicular crystal structure due to the influence of the moisture, and a porous light absorption layer is formed. If a charge transport layer is formed by being coated on such a porous light absorption layer, the charge transport material penetrates into a pore (void) of the porous light absorption layer, and a photoelectric conversion efficiency is reduced by a short circuit. In particular, as disclosed in Patent Document 1, if a conductive material with excellent conductivity (more specifically, a hole transport material) such as a carbon nanotube is used, the reduction in photoelectric conversion efficiency due to the above-mentioned short circuit is remarkable.

Therefore, the photoelectric conversion element using the perovskite compound is generally produced in an environment where the humidity is kept as low as possible (for example, in a glove box). In such an environment, the perovskite compound is formed in a plate-like crystal structure, and thus, it is possible to suppress the reduction in photoelectric conversion efficiency due to the above-mentioned short circuit. However, if the photoelectric conversion element using the perovskite compound is produced in such an environment, the production cost increases.

The present invention has been made in view of the above-mentioned problems, and an object thereof is to provide a photoelectric conversion element that has excellent photoelectric conversion efficiency and leads to a low production cost, and to provide a method of producing the same.

### SUMMARY OF THE INVENTION

A photoelectric conversion element according to the present invention includes an electron transport layer, a hole transport layer, and a light absorption layer arranged between the electron transport layer and the hole transport layer. The light absorption layer contains a perovskite compound having an acicular crystal structure. The hole transport layer contains a carbon nanotube, and a polyvinyl butyral resin.

A method of producing a photoelectric conversion element of the present invention includes a first charge transport layer formation step of forming a first charge transport layer containing a first charge transport material, a light absorption layer formation step of forming a light absorption layer on the first charge transport layer, and a second charge transport layer formation step of forming a second charge transport layer containing a second charge transporting material, on the light absorption layer. One of the first charge transport layer containing the first charge transport material and the second charge transport layer containing the second charge transport material is an electron transport layer containing an electron transporting material, and the other is a hole transport layer containing a hole transporting material. The light absorption layer contains a perovskite compound having an acicular crystal structure. The hole transport layer contains a polyvinyl butyral resin and a carbon nanotube that is the hole transporting material.

A photoelectric conversion element of the present invention and a photoelectric conversion element produced by a producing method of the present invention has excellent photoelectric conversion efficiency and leads to a low production cost.

### BRIEF DESCRIPTION OF THE DRAWINGS

FIG. 1 is a diagram illustrating an example of a photoelectric conversion element according to a first embodiment of the present invention;

FIG. 2 is a diagram illustrating another example of the photoelectric conversion element according to the first embodiment of the present invention;

FIG. 3 is a diagram illustrating a primitive unit lattice of a crystal structure of a perovskite compound;

FIG. 4 is a photograph depicting a light absorption layer formed in Example 1 of the present invention;

FIG. 5 is a photograph depicting a light absorption layer formed in Example 6 of the present invention;

FIG. 6 is a photograph depicting a hole transport layer formed in Example 1 of the present invention; and

FIG. 7 is a photograph depicting a hole transport layer formed in Example 6 of the present invention.

### DESCRIPTION OF THE PREFERRED EMBODIMENTS

Embodiments according to the present invention will be described below with reference to drawings. It is noted that the present invention is not limited to the embodiments, and can be carried out with appropriate modifications within the scope of the object of the present invention. It is noted that, in the drawings, like reference numerals may be used for identical or corresponding components to omit duplicate descriptions. Further, acrylic and methacrylic may be generally and collectively referred to as “(meth)acrylic”. Acrylates and methacrylates may be generally and collectively referred to as “(meth)acrylates”. Unless otherwise specified, various materials described in the embodiments of the present invention may be used alone or in combination of two or more kinds thereof.

### First Embodiment: Photoelectric Conversion Element

A first embodiment of the present invention relates to a photoelectric conversion element. The photoelectric conversion element according to the present embodiment includes an electron transport layer, a hole transport layer, and a light absorption layer. The light absorption layer is arranged between the electron transport layer and the hole transport layer. The light absorption layer contains a perovskite compound having an acicular crystal structure. The hole transport layer contains a carbon nanotube and a polyvinyl butyral resin.

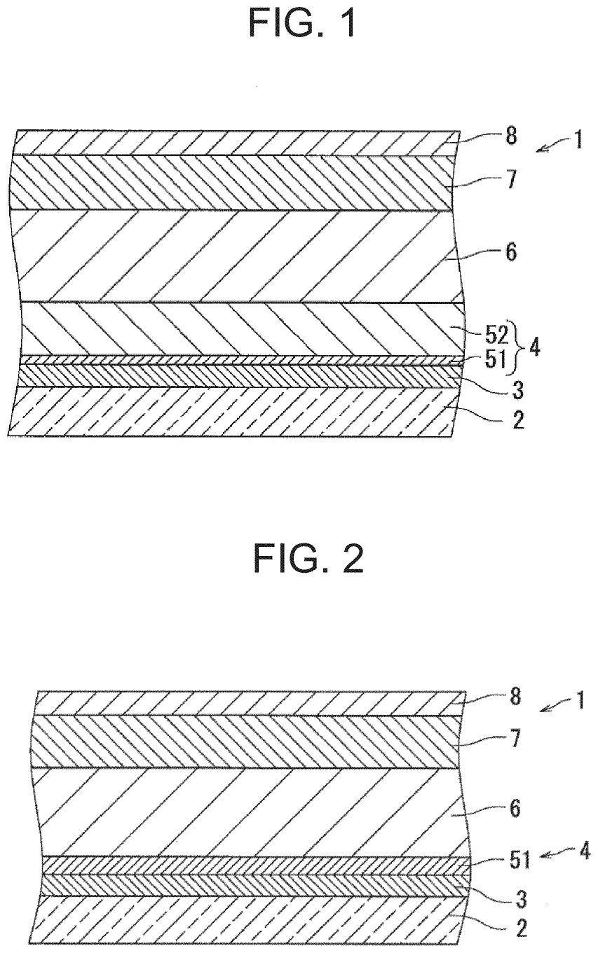

A photoelectric conversion element 1 according to the present embodiment will be described below with reference to FIGS. 1 and 2. The photoelectric conversion element 1 illustrated in FIG. 1 includes a substrate 2, a first conductive layer 3, an electron transport layer 4, a light absorption layer 6, a hole transport layer 7, and a second conductive layer 8, in order from one surface. The electron transport layer 4 has a two-layer structure including a dense titanium oxide layer 51 on a first conductive layer 3 side and a porous titanium oxide layer 52 on a light absorption layer 6 side. However, as illustrated in FIG. 2, the electron transport layer 4 may have a one-layer structure including only the dense titanium oxide layer 51. When the photoelectric conversion element 1 is used, for example, a surface on a substrate 2 side is irradiated with light (for example, sunlight). However, when the photoelectric conversion element 1 is used, a surface on a second conductive layer 8 side may be irradiated with light.

As described above, the light absorption layer 6 contains a perovskite compound having an acicular crystal structure. The hole transport layer 7 contains a carbon nanotube and a polyvinyl butyral resin. The photoelectric conversion element 1 according to the present embodiment having such a configuration has the following first, second, and third advantages.

The first advantage will be described. The light absorption layer 6 includes a porous region formed from a perovskite compound having an acicular crystal structure. Here, when a hole transport material permeates a pore (void) of the porous region provided in the light absorption layer 6 from the hole transport layer 7, an electron transport material contained in the electron transport layer 4 and the hole transport material come into close contact or into contact with each other to decrease an electrical resistance, and as a result, a short circuit between conductive layers (that is, between the first conductive layer 3 and the second conductive layer 8) may be caused. However, in the present embodiment, the hole transport layer 7 contains not only the carbon nanotube that is the hole transport material, but also the polyvinyl butyral resin. The polyvinyl butyral resin has a high affinity with the carbon nanotube, and thus, a surface of the carbon nanotube is covered with the polyvinyl butyral resin. The covering imparts an appropriate insulating property to the carbon nanotube. Conventionally, it is considered that if a resin that is an insulator such as a polyvinyl butyral resin is contained in the hole transport layer, an insulating property of the hole transport layer is enhanced, and therefore, a photoelectric conversion efficiency of the photoelectric conversion element is decreased. However, the present inventors discovered that when the carbon nanotube imparted with the appropriate insulating property by the polyvinyl butyral resin was used, it was possible to suppress the short circuit between the conductive layers even if the carbon nanotube was penetrated into the void of the porous region provided in the light absorption layer 6. The short circuit between the conductive layers is suppressed, and thus, it is possible to improve the photoelectric conversion efficiency of the photoelectric conversion element 1.

The second advantage will be described. As described in the first advantage, even if the perovskite compound having an acicular crystal structure is used for the photoelectric conversion element 1 according to the present embodiment, it is possible to suppress the short circuit between the conductive layers. Therefore, it is not necessary to produce a perovskite compound having a plate-like crystal structure in an environment where the humidity is kept as low as possible (for example, in a glove box). It is possible to produce the photoelectric conversion element 1 according to the present embodiment under air atmosphere, and thus, it is possible to reduce a production cost.

The third advantage will be described. If the polyvinyl butyral resin permeates from the hole transport layer 7 into the pore (void) of the porous region provided in the light absorption layer 6, the polyvinyl butyral resin is present between the acicular crystals of the perovskite compound, and thus, the photoelectric conversion element 1 has flexibility. Because of the flexibility, cracks and the like are unlikely to occur even if an impact is applied to the photoelectric conversion element 1. If the substrate 2 is, for example, a flexible substrate, it is possible to form the photoelectric conversion element 1 into a curved shape, and it is possible to increase a degree of freedom in the shape of the photoelectric conversion element 1. Thus, the first, second, and third advantages are described.

Substrate

Examples of the shape of the substrate 2 include a flat plate shape, a film shape, and a cylindrical shape. If the surface of the photoelectric conversion element 1 on the substrate 2 side is irradiated with light, the substrate 2 is transparent. In this case, examples of the material of the substrate 2 include transparent glass (more specifically, soda lime glass, alkali-free glass, or the like) and a transparent resin having heat resistance. If the surface of the photoelectric conversion element 1 on the second conductive layer 8 side is irradiated with light, the substrate 2 may be opaque. In this case, examples of the material of the substrate 2 include aluminum, nickel, chromium, magnesium, iron, tin, titanium, gold, silver, copper, tungsten, alloys thereof (for example, stainless steel), and ceramics.

First Conductive Layer

The first conductive layer 3 corresponds to a cathode of the photoelectric conversion element 1. Examples of the material configuring the first conductive layer 3 include a transparent conductive material and a non-transparent conductive material. Examples of the transparent conductive material include copper iodide (CuI), indium tin oxide (ITO), tin oxide (SnO₂), fluorine-doped tin oxide (FTO), aluminum-doped zinc oxide (AZO), indium zinc oxide (IZO), and gallium-doped zinc oxide (GZO). Examples of the non-transparent conductive material include sodium, a sodium-potassium alloy, lithium, magnesium, aluminum, a magnesium-silver mixture, a magnesium-indium mixture, an aluminum-lithium alloy, an aluminum-aluminum oxide mixture (Al/Al₂O₃), and an aluminum-lithium fluoride mixture (Al/LiF). A film thickness of the first conductive layer 3 is not particularly limited as long as the film thickness exhibits desired characteristics (for example, an electron transportability and transparency).

Electron Transport Layer

The electron transport layer 4 is a layer that transports electrons generated by photoexcitation in the light absorption layer 6 to the first conductive layer 3. Therefore, it is preferable that the electron transport layer 4 contains a material that can easily move the electrons generated in the light absorption layer 6 to the first conductive layer 3. The electron transport layer 4 contains, for example, titanium oxide as an electron transport material. A ratio of the titanium oxide to be contained in the electron transport layer 4 is close to 100% by mass because substantially no organic components remain if the electron transport layer 4 is sintered at a high temperature. If the electron transport layer 4 is produced at a low temperature, the electron transport layer 4 may further contain components other than the titanium oxide. An organic electron transport material may be employed for the electron transport layer 4.

As described above, the electron transport layer 4 may include, for example, the dense titanium oxide layer 51 and the porous titanium oxide layer 52 that is a porous layer. As illustrated in FIG. 2, the electron transport layer 4 may be the dense titanium oxide layer 51 having one layer. The dense titanium oxide layer 51 and the porous titanium oxide layer 52 will be described below.

Dense Titanium Oxide Layer

A porosity of the dense titanium oxide layer 51 is lower than that of the porous titanium oxide layer 52. Therefore, at the time of producing the photoelectric conversion element 1, even if a light absorption material (perovskite compound) used for forming the light absorption layer 6 passes through the porous titanium oxide layer 52, it is difficult for the light absorption material to penetrate into the dense titanium oxide layer 51. Therefore, if the photoelectric conversion element 1 is provided with the dense titanium oxide layer 51, it is possible to suppress a contact between the light absorption material and the first conductive layer 3. Further, if the photoelectric conversion element 1 is provided with the dense titanium oxide layer 51, it is possible to suppress a contact between the first conductive layer 3 and the second conductive layer 8 which causes a decrease in electromotive force. If the electron transport layer 4 includes two layers, that is, the dense titanium oxide layer 51 and the porous titanium oxide layer 52, the film thickness of the dense titanium oxide layer 51 is preferably equal to or more than 5 nm and equal to or less than 200 nm, and more preferably equal to or more than 10 nm and equal to or less than 100 nm. If the electron transport layer 4 is the dense titanium oxide layer 51 having one layer, the film thickness of the dense titanium oxide layer 51 is preferably thicker than the dense titanium oxide layer 51 having two layers and equal to or more than 200 nm and equal to or less than 1000 nm.

Porous Titanium Oxide Layer

When the photoelectric conversion element 1 includes the porous titanium oxide layer 52, the following advantages can be obtained. A porosity of the porous titanium oxide layer 52 is higher than that of the dense titanium oxide layer 51. Therefore, when the photoelectric conversion element 1 is produced, the light absorption material used for forming the light absorption layer 6 penetrates into the pore of the porous titanium oxide layer 52 and a contact area between the light absorption layer 6 and the electron transport layer 4 increases. As a result, electrons generated by photoexcitation in the light absorption layer 6 efficiently move to the electron transport layer 4. Surface irregularities of the porous titanium oxide layer 52 are larger than those of the dense titanium oxide layer 51. If the light absorption layer 6 is formed on the porous titanium oxide layer 52 having large surface irregularities, the acicular crystal of the perovskite compound does not grow too much and has an appropriate size. The void in the porous region formed of the perovskite compound having an appropriately sized acicular crystal structure grows to an appropriate size preventing a too much penetration of the hole transport material, and this further suppresses the short circuit between the conductive layers. The film thickness of the porous titanium oxide layer 52 is preferably equal to or more than 100 nm and equal to or less than 2,000 nm, and more preferably equal to or more than 200 nm and equal to or less than 1,500 nm.

Light Absorption Layer

The light absorption layer 6 is a layer that absorbs light incident on the photoelectric conversion element 1 to generate electrons and holes. Specifically, when light is incident on the light absorption layer 6, low-energy electrons contained in the light absorption material are photoexcited, and high-energy electrons and holes are generated. The generated electrons move to the electron transport layer 4. The generated holes move to the hole transport layer 7. When the electrons and the holes move, charge separation is performed.

The light absorption layer 6 contains a perovskite compound having an acicular crystal structure as a light absorption material. The light absorption layer 6 includes a porous region formed by the perovskite compound having an acicular crystal structure. At least a part of the void in the porous region of the light absorption layer 6 is filled with a carbon nanotube and a polyvinyl butyral resin permeated from the hole transport layer 7.

Perovskite Compound

The perovskite compound is a compound having a perovskite type crystal structure. The perovskite compound used in the present embodiment further includes an acicular crystal structure. As used herein, the acicular crystal structure refers to a structure in which a ratio (aspect ratio) of a major axis length relative to a minor axis length of the perovskite compound is equal to or more than 5.

The major axis length of the perovskite compound is preferably equal to or more than 5 μm and equal to or less than 50 μm, more preferably equal to or more than 7 μm and equal to or less than 20 μm, and further preferably equal to or more than 7 μm and equal to or less than 15 μm. The aspect ratio of the perovskite compound is preferably equal to or more than 5 and equal to or less than 20, more preferably equal to or more than 5 and equal to or less than 15, and further preferably equal to or more than 5 and equal to or less than 12. When the major axis length and the aspect ratio of the perovskite compound are within the above ranges, the void of the porous region formed by the perovskite compound is more easily filled with the polyvinyl butyral resin and the carbon nanotube.

It is noted that as used herein, each of the major axis length and the aspect ratio of the perovskite compound refers to an arithmetic mean value of major axis lengths of the perovskite compounds and an arithmetic mean value of the aspect ratios, and these arithmetic mean values are measured by a method described in Examples.

The acicular crystal structure of the perovskite compound can be changed by the following method. For example, as a humidity of a production environment increases, the aspect ratio of the perovskite compound also increases. In addition, as a water content of the material used in the production increases, the aspect ratio of the perovskite compound also increases. When the acicular crystal structure of the perovskite compound is formed on a surface having less irregularities, it is more likely that the major axis length and the minor axis length of the perovskite compound are shortened.

From the viewpoint of improving the photoelectric conversion efficiency, the perovskite compound is preferably a compound represented by the following general formula (1) (hereinafter, sometimes referred to as a perovskite compound (1)).

[Chem. 1]

ABX₃ (1)

In the general formula (1), A is an organic molecule, B is a metal atom, and X is a halogen atom. In the general formula (1), the three Xs may represent the same halogen atoms or different halogen atoms.

The perovskite compound (1) is an organic-inorganic hybrid compound. The organic-inorganic hybrid compound is a compound composed of an inorganic material and an organic material. The photoelectric conversion element 1 using the perovskite compound (1), which is an organic-inorganic hybrid compound, is also called an organic-inorganic hybrid photoelectric conversion element.

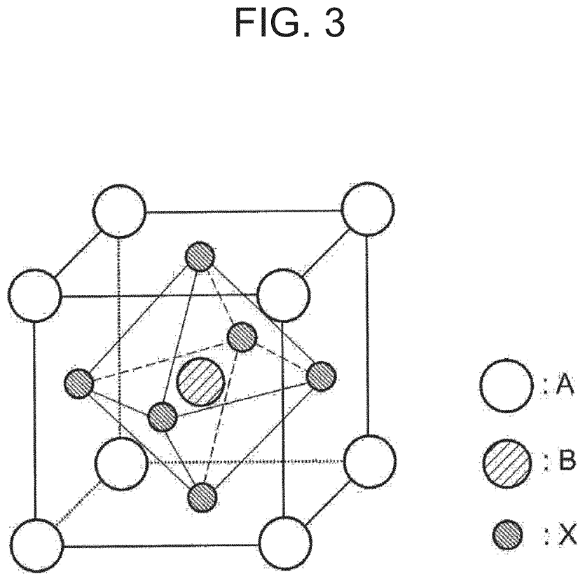

FIG. 3 illustrates a diagram of a cubic primitive unit lattice of the crystal structure of the perovskite compound (1). This primitive unit lattice includes the organic molecule A arranged at each vertex, the metal atom B arranged at a body center, and the halogen atom X arranged at each face center.

It is possible to confirm that the light absorption material includes the cubic primitive unit lattice by using an X-ray diffraction method. Specifically, the light absorption layer 6 containing the light absorption material is produced on a glass plate, the light absorption layer 6 is collected in a powder form, and a diffraction pattern of the collected powdery light absorption layer 6 (light absorption material) is measured by using a powder X-ray diffractometer. Alternatively, the light absorption layer 6 is collected from the photoelectric conversion element 1 in a powder form, and the diffraction pattern of the collected powdery light absorption layer 6 (light absorption material) is measured by using the powder X-ray diffractometer.

Examples of the organic molecule represented by A in the general formula (1) include alkylamine, alkylammonium, and a nitrogen-containing heterocyclic compound. In the perovskite compound (1), the organic molecule represented by A may be only one kind of the organic molecule or two or more kinds of the organic molecules.

Examples of the alkylamine include methylamine, ethylamine, propylamine, butylamine, pentylamine, hexylamine, dimethylamine, diethylamine, dipropylamine, dibutylamine, dipentylamine, dihexylamine, trimethylamine, triethylamine, tripropylamine, tributylamine, tripentylamine, trihexylamine, ethylmethylamine, methylpropylamine, butylmethylamine, methylpentylamine, hexylmethylamine, ethylpropylamine, and ethylbutylamine.

Alkylammonium is an ionized product of the above-mentioned alkylamines. Examples of the alkylammonium include methylammonium, ethyl ammonium, propylammonium, butyl ammonium, pentylammonium, hexylammonium, dimethylammonium, diethylammonium, dipropylammonium, dibutylammonium, dipentylammonium, dihexylammonium, trimethylammonium, triethylammonium, tripropylammonium, tributylammonium, tripentylammonium, trihexylammonium, ethylmethylammonium, methylpropylammonium, butylmethylammonium, methylpentylammonium, hexylmethylammonium, ethylpropylammonium, and ethylbutylammonium.

Examples of the nitrogen-containing heterocyclic compound include imidazole, azole, pyrrole, aziridine, azirine, azetidine, azete, azole, imidazoline, and carbazole. The nitrogen-containing heterocyclic compound may be an ionized product. Phenethylammonium is preferable as the nitrogen-containing heterocyclic compound which is an ionized product.

The organic molecule represented by A is preferably methylamine, ethylamine, propylamine, butylamine, pentylamine, hexylamine, methylammonium, ethyl ammonium, propylammonium, butyl ammonium, pentylammonium, hexylammonium or phenethylammonium, more preferably methylamine, ethylamine, propylamine, methylammonium, ethyl ammonium, or propylammonium, and still more preferably methylammonium.

In the general formula (1), examples of the metal atom represented by B include lead, tin, zinc, titanium, antimony, bismuth, nickel, iron, cobalt, silver, copper, gallium, germanium, magnesium, calcium, indium, aluminum, manganese, chromium, molybdenum, and europium. In the perovskite compound (1), the metal atom represented by B may be only one kind of the metal atom or two or more kinds of the metal atoms. From the viewpoint of improving the light absorption characteristics and the charge generation characteristics of the light absorption layer 6, the metal atom represented by B is preferably a lead atom.

In the general formula (1), examples of the halogen atom represented by X include a fluorine atom, a chlorine atom, a bromine atom, and an iodine atom. In the perovskite compound (1), the halogen atom represented by X may be one kind of the halogen atom or two or more kinds of the halogen atoms. The halogen atom represented by X is preferably an iodine atom from the viewpoint of narrowing an energy band gap of the perovskite compound (1). Specifically, out of the three Xs, at least one X preferably represents an iodine atom, and the three Xs more preferably represent an iodine atom.

The perovskite compound (1) is preferably a compound represented by the general formula “CH₃NH₃PbX₃ (where X represents a halogen atom)” and is more preferably CH₃NH₃PbI₃. If a compound represented by the general formula “CH₃NH₃PbX₃” (particularly CH₃NH₃PbI₃) is employed for the perovskite compound (1), it is possible to more efficiently generate the electrons and the holes in the light absorption layer 6, and as a result, it is possible to further improve the photoelectric conversion efficiency of the photoelectric conversion element 1.

Hole Transport Layer

The hole transport layer 7 is a layer that captures holes generated in the light absorption layer 6 and transports the captured holes to the second conductive layer 8 which is an anode. A film thickness of the hole transport layer 7 is preferably equal to or more than 20 nm and equal to or less than 2,000 nm, and more preferably equal to or more than 200 nm and equal to or less than 600 nm. When the film thickness of the hole transport layer 7 is set to equal to or more than 20 nm and equal to or less than 2,000 nm, it is possible to smoothly and efficiently move the holes generated in the light absorption layer 6 to the second conductive layer 8.

The hole transport layer 7 contains a carbon nanotube that is a hole transport material, and a polyvinyl butyral resin that is a binder resin. The hole transport layer 7 may consist only of a carbon nanotube and a polyvinyl butyral resin.

Carbon Nanotube

Examples of the carbon nanotube include a single-walled carbon nanotube and a multi-walled carbon nanotube. The carbon nanotube is preferably the multi-walled carbon nanotube. The hole transport layer 7 may consist only of a carbon nanotube as the hole transport material.

A ratio of the carbon nanotube to be contained in the hole transport layer 7 is preferably equal to or more than 10% by mass and equal to or less than 80% by mass, more preferably equal to or more than 25% by mass and equal to or less than 60% by mass, and still more preferably equal to or more than 40% by mass and equal to or less than 50% by mass. If the content ratio of the carbon nanotubes is equal to or more than 10% by mass, it is possible to improve the conductivity and easy to extract a photocurrent. On the other hand, if the content ratio of the carbon nanotube is equal to or less than 80% by mass, it is possible to further prevent the short circuit. If the content ratio of the carbon nanotube is equal to or less than 50% by mass, it is possible to further prevent the short circuit. If light is incident from the second conductive layer 8 side, it is preferable that the content of the carbon nanotube is further reduced so that the carbon nanotube is contained in a content ratio allowing the hole transport layer 7 to be translucent.

A ratio M_{C}/M_{R} of a mass M_{C} of the carbon nanotubes relative to a mass M_{R} of the polyvinyl butyral resin is preferably equal to or more than 0.3 and equal to or less than 1.0. If the ratio M_{C}/M_{R} is within the above range, an appropriate insulating property is applied to the carbon nanotube by the polyvinyl butyral resin, and thus, it is possible to further suppress the short circuit between the conductive layers.

Polyvinyl Butyral Resin

Because the polyvinyl butyral resin has excellent affinity with the carbon nanotube and imparts the appropriate insulating property to the carbon nanotube, the light absorption layer 6 contains a polyvinyl butyral resin. The polyvinyl butyral resin is soluble in a solvent (for example, isopropyl alcohol, toluene, or chlorobenzene) that does not easily affect the crystal structure of the perovskite compound contained in the light absorption layer 6. Therefore, when a hole transport layer coating liquid containing such a solvent and a polyvinyl butyral resin dissolved in the solvent is applied to the light absorption layer 6 to form the hole transport layer 7, it is possible to suppress a change in the crystal structure of the perovskite compound contained in the light absorption layer 6.

The polyvinyl butyral resin has repeating units represented by the following chemical formulas (2), (3), and (4). Hereinafter, the repeating units represented by the chemical formulas (2), (3), and (4) are sometimes described as repeating units (2), (3), and (4), respectively.

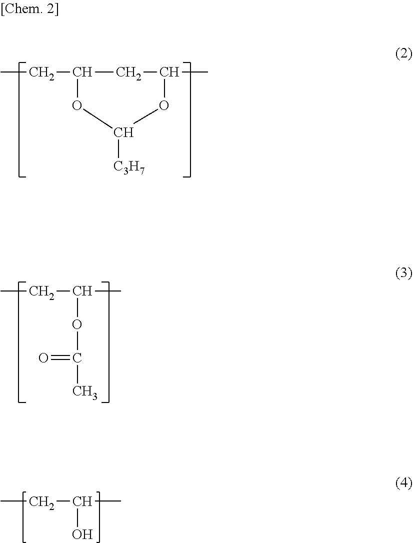

A degree of butyralization of the polyvinyl butyral resin is a percentage (unit:mol %) of the number of repeating units (2) with respect to the total number of the repeating units (2), (3), and (4) provided in the polyvinyl butyral resin. To improve the photoelectric conversion efficiency of the photoelectric conversion element 1, the degree of butyralization of the polyvinyl butyral resin is preferably equal to or more than 60 mol % and equal to or less than 80 mol %, is more preferably equal to or more than 60 mol % and equal to or less than 75 mol %, and is still more preferably equal to or more than 63 mol % and equal to or less than 74 mol %. When the degree of butyralization of the polyvinyl butyral resin is equal to or more than 60 mol %, an amount of hydroxyl groups is small, and therefore, it is difficult to absorb the moisture. On the other hand, when the degree of butyralization of the polyvinyl butyral resin is equal to or less than 80 mol %, the synthesis of the polyvinyl butyral resin is easy. It is possible to measure the degree of butyralization of the polyvinyl butyral resin by, for example, infrared spectroscopy (IR).

A weight average molecular weight of the polyvinyl butyral resin is preferably equal to or more than 1.5×10⁴ and equal to or less than 9.0×10⁴, and more preferably equal to or more than 2.0×10⁴ and equal to or less than 7.0×10⁴. It is possible to measure the weight average molecular weight of the polyvinyl butyral resin by, for example, gel permeation chromatography (GPC).

To apply an appropriate insulating property to the carbon nanotube to suppress the short circuit between the conductive layers, the carbon nanotube is preferably covered with a polyvinyl butyral resin. To efficiently pass the holes generated in the light absorption layer 6 to the hole transport layer 7, it is preferable that at least a part of the carbon nanotube and at least a part of the polyvinyl butyral resin are injected (located) in the void of the porous region provided in the light absorption layer 6. It is noted that the hole transport layer 7 may consist only the of the polyvinyl butyral resin as a binder resin.

Second Conductive Layer

The second conductive layer 8 corresponds to an anode of the photoelectric conversion element 1. Examples of the material configuring the second conductive layer 8 include a metal, a transparent conductive inorganic material, conductive microparticles, and a conductive polymer (particularly, a transparent conductive polymer). Examples of the metal include gold, silver, and platinum. Examples of the transparent conductive inorganic material include copper iodide (CuI), indium tin oxide (ITO), tin oxide (SnO₂), fluorine-doped tin oxide (FTO), aluminum-doped zinc oxide (AZO), indium zinc oxide (IZO), and gallium-doped zinc oxide (GZO). Examples of the conductive fine particles include a silver nanowire and a carbon nanofiber. Examples of the transparent conductive polymer include a polymer (PEDOT/PSS) containing poly(3,4-ethylenedioxythiophene) and polystyrene sulfonic acid.

If light is incident from the second conductive layer 8 side of the photoelectric conversion element 1, the second conductive layer 8 is preferably transparent or translucent, and more preferably transparent so that the incident light reaches the light absorption layer 6. A material configuring the transparent or translucent second conductive layer 8 is preferably a transparent conductive inorganic material or a transparent conductive polymer. A film thickness of the second conductive layer 8 is preferably equal to or more than 50 nm and equal to or less than 1,000 nm, and more preferably equal to or more than 100 nm and equal to or less than 300 nm.

Others

As described above, the photoelectric conversion element 1 which is an example of the photoelectric conversion element according to the present embodiment is described with reference to FIG. 1. However, the photoelectric conversion element according to the present embodiment is not limited to the photoelectric conversion element 1, and for example, the following features can be modified.

The photoelectric conversion element according to the present embodiment may further include a surface layer on the second conductive layer. The surface layer is a layer that suppresses deterioration of an interior of the photoelectric conversion element due to moisture and oxygen in the air. The surface layer is a layer that protects an outer surface from impact and scratches when the photoelectric conversion element is used. A material configuring the surface layer is preferably a material having a high gas barrier property. The surface layer is formed by using, for example, a resin composition, a shrink film, a wrap film, or a clear paint. On the other hand, if the photoelectric conversion element housed in a closed container is used, the photoelectric conversion element preferably does not include the surface layer. If light is incident from a surface layer side of the photoelectric conversion element, the surface layer is preferably transparent or translucent, and more preferably transparent.

The electron transport layer of the photoelectric conversion element according to the present embodiment may not need to contain titanium oxide. For example, the electron transport layer may include a dense layer including a material other than the titanium oxide and a porous layer including a material other than the titanium oxide. The electron transport layer may be a single layer or may have a multi-walled structure having three or more layers.

The photoelectric conversion element according to the present embodiment may not include the substrate, the first conductive layer, and the second conductive layer. That is, in the photoelectric conversion element, each of the substrate, the first conductive layer, and the second conductive layer may be omitted. If the photoelectric conversion element according to the present embodiment includes the substrate, the substrate may have conductivity. In this case, the substrate also functions as the first conductive layer.

### Second Embodiment: Method of Producing Photoelectric Conversion Element

A second embodiment relates to a method of producing a photoelectric conversion element. The method of producing a photoelectric conversion element according to the present embodiment includes a first charge transport layer formation step, a light absorption layer formation step, and a second charge transport layer formation step. In the first charge transport layer formation step, a first charge transport layer containing a first charge transport material is formed. In the light absorption layer formation step, a light absorption layer is formed on the first charge transport layer. In the second charge transport layer formation step, a second charge transport layer containing a second charge transport material is formed on the light absorption layer. One of the first charge transport layer containing the first charge transport material and the second charge transport layer containing the second charge transport material is an electron transport layer containing an electron transport material. The other of the first charge transport layer containing the first charge transport material and the second charge transport layer containing the second charge transport material is a hole transport layer containing a hole transport material. The light absorption layer contains a perovskite compound having an acicular crystal structure. The hole transport layer contains a polyvinyl butyral resin and a carbon nanotube as a hole transport material. The photoelectric conversion element obtained by the producing method according to the present embodiment is, for example, the photoelectric conversion element according to the first embodiment. The photoelectric conversion element obtained by the producing method according to the present embodiment has excellent photoelectric conversion efficiency and leads to a low production cost for the same reason as described in the first embodiment.

In the method of producing a photoelectric conversion element according to the present embodiment, it is preferable that the first charge transport layer containing the first charge transport material is the electron transport layer containing the electron transport material, and the second charge transport layer containing the second charge transport material is the hole transport layer containing the hole transport material. That is, in the method of producing a photoelectric conversion element according to the present embodiment, it is preferable that the electron transport layer is formed in the first charge transport layer formation step and the hole transport layer is formed in the second charge transport layer formation step.

With reference again to FIG. 1 and FIG. 2, in an example of the method of producing a photoelectric conversion element according to the present embodiment, the method of producing the photoelectric conversion element 1 will be described. The method of producing the photoelectric conversion element 1 illustrated in FIG. 1 includes, for example, a laminate preparation step of preparing a laminate including the substrate 2 and the first conductive layer 3, an electron transport layer formation step of forming the electron transport layer 4 containing the electron transport material on the first conductive layer 3 in the laminate, a light absorption layer formation step of forming the light absorption layer 6 on the electron transport layer 4, a hole transport layer formation step of forming the hole transport layer 7 containing the hole transport material on the light absorption layer 6, and a second conductive layer formation step of forming the second conductive layer 8 on the hole transport layer 7. In the producing method, the electron transport material is the first charge transport material, the electron transport layer 4 is the first charge transport layer, the electron transport layer formation step is the first charge transport layer formation step, the hole transport material is the second charge transport material, the hole transport layer 7 is the second charge transport layer, and the hole transport layer formation step is the second charge transport layer formation step.

Laminate Preparation Step

In the laminate preparation step, a laminate including the substrate 2 and the first conductive layer 3 is prepared. The laminate is obtained by forming the first conductive layer 3 on the substrate 2, for example. Examples of the method of forming the first conductive layer 3 on the substrate 2 include a vacuum deposition method, a sputtering method, and a plating method.

Electron Transport Layer Formation Step

In the electron transport layer formation step, the electron transport layer 4 containing the electron transport material is formed on the first conductive layer 3 in the laminate. Specifically, if the photoelectric conversion element 1 illustrated in FIG. 1 is produced, the step includes a dense titanium oxide layer formation step and a porous titanium oxide layer formation step. Alternatively, if the photoelectric conversion element 1 illustrated in FIG. 2 is produced, the electron transport layer formation step includes only the dense titanium oxide layer formation step.

Dense Titanium Oxide Layer Formation Step

In the dense titanium oxide layer formation step, the dense titanium oxide layer 51 is formed on the first conductive layer 3 in the laminate. Examples of the method of forming the dense titanium oxide layer 51 on the first conductive layer 3 include a method in which a dense titanium oxide layer coating liquid containing a titanium chelate compound is applied onto the first conductive layer 3, which is followed by sintering. Examples of the method of applying the dense titanium oxide layer coating liquid onto the first conductive layer 3 include a spin coating method, a screen printing method, a cast method, an immersion coating method, a roll coat method, a slot die method, a spray pyrolysis method, and an aerosol deposition method. After the sintering, the formed dense titanium oxide layer 51 may be immersed in an aqueous solution of titanium tetrachloride. As a result of this process, it is possible to increase a denseness of the dense titanium oxide layer 51.

An example of a solvent of the dense titanium oxide layer coating liquid includes alcohol (in particular, 1-butanol). Examples of the titanium chelate compound contained in the dense titanium oxide layer coating liquid include a compound having an acetoacetic ester chelate group and a compound having a β-diketone chelate group.

Examples of the compound having an acetoacetic ester chelate group include, but not particularly being limited to, diisopropoxytitanium bis(methyl acetoacetate), diisopropoxytitanium bis(ethyl acetoacetate), diisopropoxytitanium bis(propyl acetoacetate), diisopropoxytitanium bis(butyl acetoacetate), dibutoxytitanium bis(methyl acetoacetate), dibutoxytitanium bis(ethyl acetoacetate), triisopropoxytitanium (methyl acetoacetate), triisopropoxytitanium (ethyl acetoacetate), tributoxytitanium (methyl acetoacetate), tributoxytitanium (ethyl acetoacetate), isopropoxytitanium tri(methyl acetoacetate), isopropoxytitanium tri(ethyl acetoacetate), isobutoxytitanium tri(methyl acetoacetate), and isobutoxytitanium tri(ethyl acetoacetate).

Examples of the compound having a β-diketone chelate group include, but not particularly limited to, diisopropoxytitanium bis(acetylacetonate), diisopropoxytitanium bis(2,4-heptanedionate), dibutoxytitanium bis(acetylacetonate), dibutoxytitanium bis(2,4-heptanedionate), triisopropoxytitanium (acetylacetonate), triisopropoxytitanium (2,4-heptanedionate), tributoxytitanium (acetylacetonate), tributoxytitanium (2,4-heptanedionate), isopropoxytitanium tri(acetylacetonate), isopropoxytitanium tri(2,4-heptanedionate), isobutoxytitanium tri(acetylacetonate), and isobutoxytitanium tri(2,4-heptanedionate).

The titanium chelate compound is preferably a compound having an acetoacetic ester chelate group, and is more preferably diisopropoxytitanium bis(acetylacetonate). A commercially available product such as the “TYZOR (registered trademark) AA” series produced by DuPont may be employed for the titanium chelate compound.

Porous Titanium Oxide Layer Formation Step

In the porous titanium oxide layer formation step, the porous titanium oxide layer 52 is formed on the dense titanium oxide layer 51. Examples of the method of forming the porous titanium oxide layer 52 include a method in which a porous titanium oxide layer coating liquid containing a titanium oxide is applied onto the dense titanium oxide layer 51, which is followed by sintering. The porous titanium oxide layer coating liquid may further contain, for example, a solvent and an organic binder. If the porous titanium oxide layer coating liquid contains the organic binder, the organic binder is removed by sintering. Examples of the method of applying the porous titanium oxide layer coating liquid onto the dense titanium oxide layer 51 include a spin coating method, a screen printing method, a cast method, an immersion coating method, a roll coat method, a slot die method, a spray pyrolysis method, and an aerosol deposition method.

A pore diameter and a porosity of the porous titanium oxide layer 52 can be adjusted, for example, by adjusting a particle size of titanium oxide particles contained in the porous titanium oxide layer coating liquid, and a type and a content of the organic binder.

Examples of the titanium oxide contained in the porous titanium oxide layer coating liquid include, but not particularly limited to, anatase-type titanium oxide. The porous titanium oxide layer coating liquid can be prepared by dispersing, for example, titanium oxide particles (more specifically, “AEROXIDE (registered trademark) TiO₂ P25” produced by NIPPON AEROSIL Co., Ltd., and the like) into alcohol (more specifically, ethanol and the like). The porous titanium oxide layer coating liquid can be prepared by diluting, for example, a titanium oxide paste (more specifically, “PST-18NR” produced by JGC Catalysts and Chemicals Ltd., and the like) with alcohol (more specifically, ethanol or the like).

If the porous titanium oxide layer coating liquid contains the organic binder, the organic binder is preferably ethyl cellulose or acrylic resin. The acrylic resin has excellent low-temperature decomposability, and organic substances are unlikely to remain in the porous titanium oxide layer 52 even when being sintered at a low temperature. The acrylic resin is preferably decomposed at a temperature of about 300° C. Examples of the acrylic resin include polymers of at least one (meth)acrylic monomer. Examples of the (meth)acrylic monomer include methyl (meth)acrylate, ethyl (meth)acrylate, propyl (meth)acrylate, n-butyl (meth)acrylate, tert-butyl (meth)acrylate, isobutyl (meth)acrylate, cyclohexyl (meth)acrylate, 2-ethylhexyl (meth)acrylate, isobornyl (meth)acrylate, n-stearyl (meth)acrylate, benzyl (meth)acrylate, and (meth)acrylic monomers having a polyoxyalkylene structure.

Light Absorption Layer Formation Step

In the light absorption layer formation step, the light absorption layer 6 is formed on the electron transport layer 4 (specifically, on the porous titanium oxide layer 52 illustrated in FIG. 1 or on the dense titanium oxide layer 51 illustrated in FIG. 2). The light absorption layer 6 is a porous layer containing the perovskite compound having an acicular crystal structure. The perovskite compound having an acicular crystal structure can be produced more stably than a perovskite compound having a plate-like crystal structure, and has an excellent yield.

If the perovskite compound is the perovskite compound (1), the light absorption layer 6 can be formed by, for example, the following one-step method or two-step method.

In the one-step method, a solution containing a compound represented by the general formula “AX” (hereinafter, referred to as compound (AX)) and a solution containing a compound represented by the general formula “BX₂” (hereinafter, referred to as compound (BX₂)) are mixed to obtain a mixture. A, B, and X in the general formula “AX” and the general formula “BX₂” are synonymous with A, B, and X in the general formula (1), respectively. When this mixture is applied on the electron transport layer 4 and the resultant mixture is dried, a porous layer containing the perovskite compound (1) represented by the general formula “ABX₃” is formed. Examples of the method of applying the mixture onto the electron transport layer 4 include an immersion coating method, a roll coat method, a spin coating method, and a slot die method.

In the two-step method, a solution containing the compound (BX₂) is applied onto the electron transport layer 4 to form a coating film. A solution containing the compound (AX) is applied onto the coating film, and the compound (BX₂) and the compound (AX) are reacted in the coating film. Next, the coating film is dried to form a porous layer containing the perovskite compound (1) represented by the general formula “ABX₃”. Examples of a method of applying the solution containing the compound (BX₂) to the electron transport layer 4 and a method of applying the solution containing the compound (AX) onto the coating film include an immersion coating method, a roll coat method, a spin coating method, and a slot die method.

Under air atmosphere (under a normal environment), the perovskite compound (1) having an acicular crystal structure is formed by the influence of humidity in either the one-step method or the two-step method. The light absorption layer 6 is formed by application under air atmosphere, and thus, with the producing method according to the present embodiment, it is possible to produce the photoelectric conversion element 1 at low cost.

In the light absorption layer formation step, in addition to the above methods, for example, a light absorption layer coating liquid containing the perovskite compound and a binder resin may be applied on the electron transport layer 4.

Hole Transport Layer Formation Step

In the hole transport layer formation step, the hole transport layer 7 containing the hole transport material is formed on the light absorption layer 6. In particular, when a hole transport layer coating liquid is applied on the light absorption layer 6, the hole transport layer 7 is formed. The hole transport layer coating liquid contains a polyvinyl butyral resin, a carbon nanotube that is the hole transport material, and a solvent.

The solvent contained in the hole transport layer coating liquid is preferably an organic solvent, more preferably an organic solvent in which the light absorption layer 6 is not dissolved but the polyvinyl butyral resin is dissolved, and still more preferably isopropyl alcohol, toluene, or chlorobenzene. When the solvent in which the light absorption layer 6 is not dissolved is used, it is possible to suitably maintain the acicular crystal structure of the perovskite compound in the light absorption layer 6. When the solvent in which the polyvinyl butyral resin is dissolved is used, the carbon nanotube is thinly and evenly covered with the polyvinyl butyral resin in a dissolved state, and thus, it is possible to impart an appropriate insulating property to the carbon nanotube. A ratio of the carbon nanotubes to be contained in the hole transport layer coating liquid is, for example, equal to or more than 0.5% by mass and equal to or less than 5.0% by mass. A ratio of the polyvinyl butyral resin to be contained in the hole transport layer coating liquid is, for example, equal to or more than 0.5% by mass and equal to or less than 5.0% by mass.

The hole transport layer coating liquid is prepared by feeding and dispersing the carbon nanotube and the polyvinyl butyral resin in a solvent. For dispersion, for example, a homogenizer or an ultrasonic disperser is used. The carbon nanotube is destructed when receiving a strong share, and thus, it is preferable to set a gentle dispersion condition.

Examples of a method of applying the hole transport layer coating liquid include an immersion coating method, a spray coating method, a slide hopper coating method, a roll coat method, and a spin coating method. The hole transport layer coating liquid is preferably applied by the immersion coating method, the roll coat method, or the spin coating method.

Second Conductive Layer Formation Step

In the second conductive layer formation step, the second conductive layer 8 is formed on the hole transport layer 7. Examples of a method of forming the second conductive layer 8 on the hole transport layer 7 include, but not particularly limited to, the same method as the method of forming the first conductive layer 3 (more specifically, a vacuum deposition method, a sputtering method, a plating method, and the like).

Others

As described above, in an example of the method of producing a photoelectric conversion element according to the present embodiment, the method of producing the photoelectric conversion element 1 illustrated in FIGS. 1 and 2 is described. However, the method of producing a photoelectric conversion element according to the present embodiment is not limited to the above-mentioned producing method, and for example, the following features can be modified.

The method of producing a photoelectric conversion element according to the present embodiment may further include a surface layer formation step of forming a surface layer on the second conductive layer. The method of producing a photoelectric conversion element according to the present embodiment may not need to include the laminate preparation step and the second conductive layer formation step. In the electron transport layer formation step, the electron transport layer may be formed by using any method other than the dense titanium oxide layer formation step and the porous titanium oxide layer formation step described above.

### EXAMPLES

The present invention will be further described below with reference to examples. However, the present invention is not limited to the examples.

Production of Photoelectric Conversion Element

Photoelectric conversion elements (A-1) to (A-10) and (B-1) to (B-2) shown in Table 1 were produced by the following methods. A production environment of each photoelectric conversion element was an environment where a temperature was 25° C. and a humidity was 60% RH.

TABLE 1

| | | | Hole transport layer | | | |
|---|---|---|---|---|---|---|
| | | | Resin | | | |
| | Photoelectric | Electron | | Degree of | | |
| | conversion | transport | | butyralization | | |
| | element | layer | Type | [mol %] | CNT/resin | Solvent |
| Example 1 | A-1 | 2-layered | BL-S | 74 | 1.0 | Isopropyl |
| | | titanium | | | | alcohol |
| | | oxide | | | | |
| Example 2 | A-2 | 2-layered | BM-S | 73 | 1.0 | Isopropyl |
| | | titanium | | | | alcohol |
| | | oxide | | | | |
| Example 3 | A-3 | 2-layered | BH-S | 73 | 1.0 | Isopropyl |
| | | titanium | | | | alcohol |
| | | oxide | | | | |
| Example 4 | A-4 | 2-layered | BL-1 | 63 | 1.0 | Isopropyl |
| | | titanium | | | | alcohol |
| | | oxide | | | | |
| Example 5 | A-5 | 2-layered | BL-S | 74 | 1.0 | Toluene |
| | | titanium | | | | |
| | | oxide | | | | |
| Example 6 | A-6 | 1-layered | BL-S | 74 | 1.0 | Isopropyl |
| | | dense | | | | alcohol |
| | | titanium | | | | |
| | | oxide | | | | |
| Example 7 | A-7 | 2-layered | BL-S | 74 | 1.0 | Chlorobenzene |
| | | titanium | | | | |
| | | oxide | | | | |
| Example 8 | A-8 | 2-layered | BL-S | 74 | 0.3 | Isopropyl |
| | | titanium | | | | alcohol |
| | | oxide | | | | |
| Example 9 | A-9 | 2-layered | BL-S | 74 | 0.2 | Isopropyl |
| | | titanium | | | | alcohol |
| | | oxide | | | | |
| Example 10 | A-10 | 2-layered | BL-S | 74 | 1.3 | Isopropyl |
| | | titanium | | | | alcohol |
| | | oxide | | | | |
| Comparative | B-1 | 2-layered | — | — | — | Toluene |
| Example 1 | | titanium | | | (CNT only) | |
| | | oxide | | | | |
| Comparative | B-2 | 2-layered | PMMA | — | 1.0 | Methyl ethyl |
| Example 2 | | titanium | | | | ketone |
| | | oxide | | | | |

It is noted that meanings of the terms used in Table 1 are as follows. “2-layered titanium oxide” indicates that the electron transport layer has a two-layer structure including a dense titanium oxide layer and a porous titanium oxide layer. “1-layered dense titanium oxide layer” indicates that the electron transport layer has a one-layer structure consisting only of a dense titanium oxide layer. “CNT/resin” indicates a ratio of the mass of the carbon nanotube relative to the mass of resin in the hole transport layer. A ratio of the mass of the carbon nanotube relative to the mass of resin indicates a value rounded down to one decimal place. “−” indicates that a corresponding component is not present or there is no corresponding value. “-(CNT only)” means that the hole transport layer does not contain the resin but contains the carbon nanotube only, and thus, it is not possible to calculate a ratio of the mass of the carbon nanotube relative to the mass of the resin, in the hole transport layer.

Resins shown in “resin” columns of the “hole transport layer” in Table 1 are as follows:

BL-S: Polyvinyl butyral resin (“Eslek BL-S” produced by SEKISUI CHEMICAL CO., LTD., degree of butyralization 74 mol %);

BM-S: Polyvinyl butyral resin (“Eslek BM-S” produced by SEKISUI CHEMICAL CO., LTD., degree of butyralization 73 mol %);

BH-S: Polyvinyl butyral resin (“Eslek BH-S” produced by SEKISUI CHEMICAL CO., LTD., degree of butyralization 73 mol %);

BL-1: Polyvinyl butyral resin (“Eslek BL-1” produced by SEKISUI CHEMICAL CO., LTD., degree of butyralization 63 mol %); and

PMMA: Polymethyl methacrylate resin (“Methyl methacrylate polymer” produced by Tokyo Chemical Industry Co., Ltd.).

Photoelectric Conversion Element (A-1)

Laminate Preparation Step

A transparent glass plate on which fluorine-doped tin oxide was deposited (produced by Sigma-Aldrich Co. LLC, film thickness: 2.2 mm) was cut into a piece having a size of 25 mm in width and 25 mm in length. As a result, a laminate including a substrate (transparent glass plate) and a first conductive layer (fluorine-doped tin oxide film) was prepared. The laminate was subjected to ultrasonic cleaning treatment (for 10 minutes) and UV cleaning treatment (for 15 minutes) in ethanol.

Dense Titanium Oxide Layer Formation Step

A 1-butanol solution (produced by Sigma-Aldrich Co. LLC) containing diisopropoxytitanium bis (acetylacetonate), which is a titanium chelate compound, at a concentration of 75% by mass was diluted with 1-butanol. As a result, a dense titanium oxide layer coating liquid having the concentration of a titanium chelate compound of 0.02 mol/L was prepared. The dense titanium oxide layer coating liquid was applied onto the first conductive layer in the above-mentioned laminate by a spin coating method, and heated at 450° C. for 15 minutes. As a result, the dense titanium oxide layer having a film thickness of 50 nm was formed on the first conductive layer.

Porous Titanium Oxide Layer Formation Step

1 g of a titanium oxide paste containing titanium oxide and ethanol (“PST-18NR” produced by JGC Catalysts and Chemicals Ltd.) was diluted with 2.5 g of ethanol to prepare a porous titanium oxide layer coating liquid. The porous titanium oxide layer coating liquid was applied onto the above-mentioned dense titanium oxide layer by using a spin coating method, and then sintered at 450° C. for one hour. As a result, the porous titanium oxide layer having a film thickness of 300 nm was formed on the dense titanium oxide layer.

Light Absorption Layer Formation Step

The light absorption layer was formed under air atmosphere. 922 mg of PbI₂ (produced by Tokyo Chemical Industry Co., Ltd.) and 318 mg of CH₃NH₃I (produced by Tokyo Chemical Industry Co., Ltd.) were dissolved by heating in 1.076 mL of N, N-dimethylformamide (DMF). A molar ratio of PbI₂ and CH₃NH₃I was 1:1. As a result, a mixture having a solid content concentration of 55% by mass was prepared. This mixture was applied onto the above-mentioned porous titanium oxide layer by a spin coating method. When a few drops of toluene were dropped on a liquid film immediately after the application, the liquid film changed in color from yellow to black. As a result, it was confirmed that the perovskite compound (CH₃NH₃PbI) was formed. This was followed by drying of the liquid film at 100° C. for 60 minutes. As a result, a light absorption layer having a film thickness of 500 nm containing the perovskite compound was formed on the porous titanium oxide layer.

Hole Transport Layer Formation Step

Using an ultrasonic disperser, 0.2 g of carbon nanotube (multi-walled carbon nanotube, “Carbon Nanotube Multi-walled” produced by Tokyo Chemical Industry Co., Ltd.) and 0.2 g of polyvinyl butyral resin (“Eslek BL-S” produced by SEKISUI CHEMICAL CO., LTD., weight average molecular weight: 2.3×10⁴) were dispersed in 12.21 mL of isopropyl alcohol. As a result, a hole transport layer coating liquid was prepared. The hole transport layer coating liquid was applied onto the above-mentioned light absorption layer by a spin coating method. This was followed by drying the applied hole transport layer coating liquid at 100° C. for 30 minutes to remove an organic solvent (isopropyl alcohol). As a result, a hole transport layer having a film thickness of 500 nm was formed on the above-mentioned light absorption layer.

Second Conductive Layer Formation Step

The second conductive layer was formed on the hole transport layer described above by a vacuum deposition method. The second conductive layer was a gold-deposited film having a film thickness of 150 nm, a width of 5 mm, and a length of 5 mm, and was provided as an anode. As a result, the photoelectric conversion element (A-1) including the substrate, the first conductive layer, the electron transport layer (more particularly, the dense titanium oxide layer and the porous titanium oxide layer), the light absorption layer, the hole transport layer, and the second conductive layer, was obtained.

The photoelectric conversion elements (A-2) to (A-10) and (B-1) and (B-2) were produced by using the same method as that of producing the photoelectric conversion element (A-1) except that the following features are changed.

Photoelectric Conversion Element (A-2)

In producing the photoelectric conversion element (A-2), in the hole transport layer formation step, instead of 0.2 g of polyvinyl butyral resin (“Eslek BL-S” produced by SEKISUI CHEMICAL CO., LTD.), 0.2 g of polyvinyl butyral resin (“Eslek BM-S” produced by SEKISUI CHEMICAL CO., LTD., weight average molecular weight: 5.3×10⁴) was used.

Photoelectric Conversion Element (A-3)

In producing the photoelectric conversion element (A-3), in the hole transport layer formation step, instead of 0.2 g of polyvinyl butyral resin (Eslek BL-S” produced by SEKISUI CHEMICAL CO., LTD.), 0.2 g of polyvinyl butyral resin (“Eslek BH-S” produced by SEKISUI CHEMICAL CO., LTD., weight average molecular weight: 6.6×10⁴) was used.

Photoelectric Conversion Element (A-4)

In producing the photoelectric conversion element (A-4), in the hole transport layer formation step, instead of 0.2 g of polyvinyl butyral resin (“Eslek BL-S” produced by SEKISUI CHEMICAL CO., LTD.), 0.2 g of polyvinyl butyral resin (“Eslek BL-1” produced by SEKISUI CHEMICAL CO., LTD., weight average molecular weight: 1.9×10⁴) was used.

Photoelectric Conversion Element (A-5)

In producing the photoelectric conversion element (A-5), in the hole transport layer formation step, instead of 12.21 mL of isopropyl alcohol, 11.13 mL of toluene was used.

Photoelectric Conversion Element (A-6)

In producing the photoelectric conversion element (A-6), the porous titanium oxide layer formation step implemented in producing the photoelectric conversion element (A-1) was not implemented. Further, in producing the photoelectric conversion element (A-6), the dense titanium oxide layer formation step, which was implemented once in producing the photoelectric conversion element (A-1), was implemented twice.

Photoelectric Conversion Element (A-7)

In producing the photoelectric conversion element (A-7), in the hole transport layer formation step, 8.6 mL of chlorobenzene was used instead of 12.21 mL of isopropyl alcohol, and a drying temperature of the applied hole transport layer coating liquid was changed from 100° C. to 130° C.

Photoelectric Conversion Element (A-8)

In producing the photoelectric conversion element (A-8), in the hole transport layer formation step, an amount of carbon nanotube to be added was changed from 0.2 g to 0.1 g, and an amount of polyvinyl butyral resin (“Eslek BL-S” produced by SEKISUI CHEMICAL CO., LTD.) to be added was changed from 0.2 g to 0.3 g.

Photoelectric Conversion Element (A-9)

In producing the photoelectric conversion element (A-9), in the hole transport layer formation step, an amount of carbon nanotube to be added was changed from 0.2 g to 0.08 g, and an amount of polyvinyl butyral resin (“Eslek BL-S” produced by SEKISUI CHEMICAL CO., LTD.) to be added was changed from 0.2 g to 0.32 g.

Photoelectric Conversion Element (A-10)

In producing the photoelectric conversion element (A-10), in the hole transport layer formation step, the amount of carbon nanotube to be added was kept unchanged at 0.2 g, and an amount of polyvinyl butyral resin (“Eslek BL-S” produced by SEKISUI CHEMICAL CO., LTD.) to be added was changed from 0.2 g to 0.15 g.

Photoelectric Conversion Element (B-1)

In producing the photoelectric conversion element (B-1), in the hole transport layer formation step, the polyvinyl butyral resin (“Eslek BL-S” produced by SEKISUI CHEMICAL CO., LTD.) was not added. That is, a hole transport layer coating liquid (carbon nanotube dispersion liquid containing no binder resin) obtained by dispersing 0.2 g of carbon nanotubes in 12.21 mL of isopropyl alcohol, was used.

Photoelectric Conversion Element (B-2)

In producing the photoelectric conversion element (B-2), in the hole transport layer formation step, instead of the polyvinyl butyral resin (“Eslek BL-S” produced by SEKISUI CHEMICAL CO., LTD.), polymethyl methacrylate resin (“Methyl methacrylate polymer” produced by Tokyo Chemical Industry Co., Ltd.) was used. The polymethyl methacrylate resin was not dissolved in isopropyl alcohol, toluene, and chlorobenzene, and thus, methyl ethyl ketone was used instead of isopropyl alcohol.

Observation of Light Absorption Layer

After the light absorption layer formation step and before the hole transport layer formation step, the light absorption layers of the photoelectric conversion elements (A-1) and (A-6) were observed.

Observation of Light Absorption Layer of Photoelectric Conversion Element (A-1)

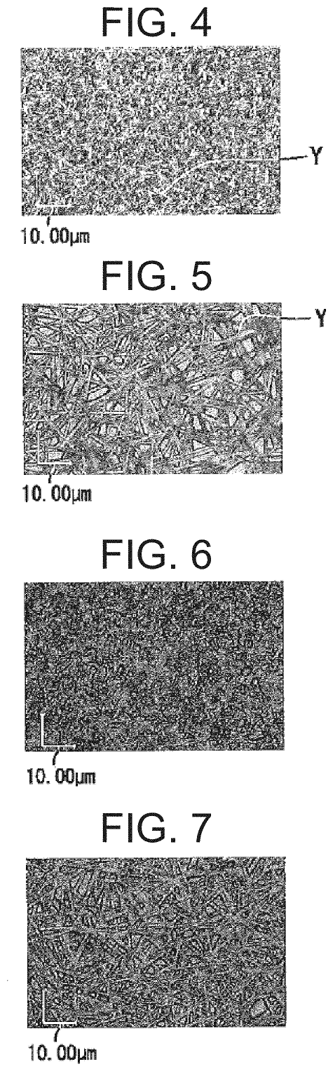

A surface of the light absorption layer of the photoelectric conversion element (A-1) was observed at a magnification of 2000 by using an optical microscope (“Digital Microscope VHX” produced by KEYENCE CORPORATION). FIG. 4 depicts a photograph of the observed surface of the light absorption layer of the photoelectric conversion element (A-1). It is noted that scale bars shown in the photographs of FIG. 4 and FIGS. 5 to 7 described later indicate a length of 10.00 μm. From the photograph depicted in FIG. 4, it was confirmed that the light absorption layer of the photoelectric conversion element (A-1) was configured by a perovskite compound Y having an acicular crystal structure and the porous region was formed by the perovskite compound Y having the acicular crystal structure.

Observation of Light Absorption Layer of Photoelectric Conversion Element (A-6)

A surface of the light absorption layer of the photoelectric conversion element (A-6) was observed at a magnification of 2000 by using an optical microscope (“Digital Microscope VHX” produced by KEYENCE CORPORATION). FIG. 5 shows a photograph of the observed surface of the light absorption layer of the photoelectric conversion element (A-6). From the photograph illustrated in FIG. 5, it was confirmed that the light absorption layer of the photoelectric conversion element (A-6) was configured by the perovskite compound Y having an acicular crystal structure and the porous region was formed by the perovskite compound Y having the acicular crystal structure. Further, from the photographs illustrated in FIGS. 4 and 5, it was confirmed that as compared to the acicular crystal of the perovskite compound Y contained in the light absorption layer of the photoelectric conversion element (A-1), the acicular crystal of the perovskite compound Y contained in the light absorption layer of the photoelectric conversion element (A-6) was greatly grown. Compared with a surface of the electron transport layer (porous titanium oxide layer) of the photoelectric conversion element (A-1), the surface of the electron transport layer (dense titanium oxide layer) of the photoelectric conversion element (A-6) had few irregularities, and thus, it is considered that the acicular crystal of the perovskite compound Y was greatly grown.

Measurement of Major Axis Length and Aspect Ratio of Perovskite Compounds

After the light absorption layer formation step and before the hole transport layer formation step, the light absorption layers of the photoelectric conversion elements (A-1) and (A-6) were observed and the major axis length and the aspect ratio of the perovskite compound were measured.

Measurement of Photoelectric Conversion Element (A-1)

A surface of the light absorption layer of the photoelectric conversion element (A-1) was observed at a magnification of 2000 by using an optical microscope (“Digital Microscope VHX” produced by KEYENCE CORPORATION). The major axis lengths and the aspect ratios of any 20 perovskite compounds confirmed on the surface of the light absorption layer were measured, and a total of 20 measurement values were divided by the number (20) of the perovskite compounds to be measured to evaluate an arithmetic mean value. In the perovskite compound contained in the light absorption layer of the photoelectric conversion element (A-1), the arithmetic mean value of the major axis length was 7 μm and the arithmetic mean value of the aspect ratio was 5.

Measurement of Photoelectric Conversion Element (A-6)

By using the same measurement method as that of the photoelectric conversion element (A-1), the major axis length and the aspect ratio of the perovskite compound contained in the light absorption layer of the photoelectric conversion element (A-6) were measured and the arithmetic mean value thereof was evaluated. In the perovskite compound contained in the light absorption layer of the photoelectric conversion element (A-6), the arithmetic mean value of the major axis length was 15 μm and the arithmetic mean value of the aspect ratio was 12.

Observation of Hole Transport Layer

After the hole transport layer formation step and before the second conductive layer formation step, surfaces of the hole transport layers of the photoelectric conversion elements (A-1) and (A-6) were observed at a magnification of 2000 by using an optical microscope (“Digital Microscope VHX” produced by KEYENCE CORPORATION). FIG. 6 shows a photograph of the observed surface of the hole transport layer of the photoelectric conversion element (A-1). FIG. 7 shows a photograph of the observed surface of the hole transport layer of the photoelectric conversion element (A-6). From the photographs shown in FIGS. 6 and 7, it was confirmed that the void of the porous region of the light absorption layer formed by the perovskite compound Y having an acicular crystal structure was filled with the carbon nanotube and the polyvinyl butyral resin. Further, from the photographs illustrated in FIGS. 6 and 7, it was confirmed that even if the void of the porous region of the light absorption layer was large, there were no pinholes on the surface of the hole transport layer. There are no pinholes on the surface of the hole transport layer, and thus, it is determined that a short circuit between the conductive layers is prevented.

Evaluation

In each of the photoelectric conversion elements (A-1) to (A-10) and (B-1) and (B-2), short circuit currents, open circuit voltages, fill factors, and photoelectric conversion efficiency were measured by using a solar simulator (produced by WACOM ELECTRIC CO., LTD.). The photoelectric conversion element was connected to the solar simulator so that the second conductive layer on a surface layer side of the photoelectric conversion element is an anode and the first conductive layer on a substrate side is a cathode. The photoelectric conversion element was irradiated with 100 mW/cm² of pseudo-sunlight obtained by passing light of a xenon lamp through an air mass filter (“AM-1.5” produced by Nikon Corporation). Current-voltage characteristics of the photoelectric conversion element during the irradiation were measured, and a current-voltage curve was obtained. From the current-voltage curve, a short circuit current (Jsc), an open circuit voltage (Voc), a fill factor (FF), and a photoelectric conversion efficiency (η) were calculated. A higher value in any of the short-circuit current, the open circuit voltage, the fill factor, and the photoelectric conversion efficiency indicates a more excellent photoelectric conversion element. The results are shown in Table 2 below.

TABLE 2

| | | Short | Open | | |
|---|---|---|---|---|---|
| | Photoelectric | circuit | circuit | Fill | Conversion |
| | conversion | current | voltage | factor | Efficiency |
| | element | [mA/cm²] | [V] | [%] | [%] |
| Example 1 | A-1 | 27.1 | 0.78 | 0.33 | 7.0 |
| Example 2 | A-2 | 26.8 | 0.81 | 0.36 | 7.8 |
| Example 3 | A-3 | 31.5 | 0.83 | 0.35 | 9.2 |
| Example 4 | A-4 | 29.2 | 0.79 | 0.34 | 7.8 |
| Example 5 | A-5 | 34.6 | 0.81 | 0.39 | 10.9 |
| Example 6 | A-6 | 28.1 | 0.77 | 0.31 | 6.7 |
| Example 7 | A-7 | 30.5 | 0.85 | 0.31 | 8.0 |
| Example 8 | A-8 | 25.6 | 0.92 | 0.33 | 7.8 |
| Example 9 | A-9 | 28.0 | 0.67 | 0.33 | 6.2 |
| Example 10 | A-10 | 23.1 | 0.87 | 0.32 | 6.4 |
| Comparative | B-1 | 13.3 | 0.48 | 0.29 | 1.9 |
| Example 1 | | | | | |
| Comparative | B-2 | 2.1 | 0.02 | 0.21 | 0.0 |
| Example 2 | | | | | |

The light absorption layers of the photoelectric conversion elements (A-1) to (A-10) contained the perovskite compound having the acicular crystal structure, and the hole transport layer contained the carbon nanotube and the polyvinyl butyral resin. Therefore, as shown in Table 2, the photoelectric conversion elements (A-1) to (A-10) exhibited good performance in the short circuit current, the open circuit voltage, the fill factor, and the conversion efficiency as compared to the photoelectric conversion elements (B-1) and (B-2). Further, it is possible to form the light absorption layer under air atmosphere in the photoelectric conversion elements (A-1) to (A-10), and thus, it is determined that the photoelectric conversion elements (A-1) to (A-10) are produced at low cost.

Further, in the hole transport layers of the photoelectric conversion elements (A-1) to (A-8), a ratio of a mass of the carbon nanotube relative to a mass of the polyvinyl butyral resin was equal to or more than 0.3 and equal to or less than 1.0. Therefore, as shown in Table 2, the photoelectric conversion elements (A-1) to (A-8) out of the photoelectric conversion elements (A-1) to (A-10) showed particularly good conversion efficiencies.

On the other hand, the photoelectric conversion elements (B-1) exhibited poor performance in the short circuit current, the open circuit voltage, the fill factor, and the photoelectric conversion efficiency as compared to the photoelectric conversion elements (A-1) to (A-10). This is probably due to a feature that in the photoelectric conversion element (B-1), during the formation of the hole transport layer, the carbon nanotube that is the hole transport material penetrated into the void in the porous region of the light absorption layer without being covered with the polyvinyl butyral resin, as a result of which a short circuit between the conductive layers was partially generated.

Further, the photoelectric conversion elements (B-2) exhibited poor performance in the short circuit current, the open circuit voltage, the fill factor, and the photoelectric conversion efficiency as compared to the photoelectric conversion elements (A-1) to (A-10). This is probably because the methyl ethyl ketone used in the hole transport layer formation step destructed the acicular crystal structure of the perovskite compound contained in the light absorption layer.

### INDUSTRIAL APPLICABILITY

The photoelectric conversion element according to the present invention can be utilized for a solar power generation system such as a mega solar system, a solar cell, and a power source for a small portable device.

What is claimed is:

1. A photoelectric conversion element, comprising:
an electron transport layer; a hole transport layer; and a light absorption layer arranged between the electron transport layer and the hole transport layer, wherein
the light absorption layer contains a perovskite compound having an acicular crystal structure, and
the hole transport layer contains a carbon nanotube and a polyvinyl butyral resin.

2. The photoelectric conversion element according to claim 1, wherein a degree of butyralization of the polyvinyl butyral resin is equal to or more than 60 mol % and equal to or less than 80 mol %.

3. The photoelectric conversion element according to claim 1, wherein a ratio of a mass of the carbon nanotube relative to a mass of the polyvinyl butyral resin is equal to or more than 0.3 and equal to or less than 1.0.

4. The photoelectric conversion element according to claim 1, wherein a major axis length of the perovskite compound is equal to or more than 5 μm and equal to or less than 50 μm, and
a ratio of the major axis length relative to a minor axis length of the perovskite compound is equal to or more than 5 and equal to or less than 20.

5. The photoelectric conversion element according to claim 1, wherein the perovskite compound is represented by the following general formula (1):
[Chem. 1]
ABX₃ (1)
(in the general formula (1), A is an organic molecule, B is a metal atom, and X is a halogen atom).

6. The photoelectric conversion element according to claim 1, wherein the electron transport layer contains titanium oxide.

7. A method of producing a photoelectric conversion element, comprising:
forming a first charge transport layer containing a first charge transport material;
forming a light absorption layer on the first charge transport layer; and
forming a second charge transport layer containing a second charge transporting material, on the light absorption layer, wherein
one of the first charge transport layer containing the first charge transport material and the second charge transport layer containing the second charge transport material is an electron transport layer containing an electron transporting material, and the other is a hole transport layer containing a hole transporting material,
the light absorption layer contains a perovskite compound having an acicular crystal structure, and
the hole transport layer contains a polyvinyl butyral resin and a carbon nanotube that is the hole transporting material.

8. The method of producing a photoelectric conversion element according to claim 7, wherein the first charge transport layer containing the first charge transport material is the electron transport layer containing the electron transport material,
the second charge transport layer containing the second charge transport material is the hole transport layer containing the hole transport material,
in the forming the second charge transport layer, the hole transport layer is formed by applying a hole transport layer coating liquid on the light absorption layer, and
the hole transport layer coating liquid contains the polyvinyl butyral resin, the carbon nanotube that is the hole transport material, and a solvent.

9. The method of producing a photoelectric conversion element according to claim 8, wherein the solvent contained in the hole transport layer coating liquid is isopropyl alcohol, toluene, or chlorobenzene.

10. The method of producing a photoelectric conversion element according to claim 8, wherein the hole transport layer coating liquid is applied by an immersion coating method, a roll coat method, or a spin coating method.
